(19) United States
(12) Patent Application Publication
(10) Pub. No.: US 2026/0111628 A1
(43) Pub. Date: Apr. 23, 2026

(54) TRANSFER LEARNING METHOD FOR CORE-LOGS INTEGRATION

(71) Applicant: SCHLUMBERGER TECHNOLOGY CORPORATION, Sugar Land, TX (US)

(72) Inventors: Laurent MOSSE, Paris (FR); Chiara CAVALLERI, Al-Khobar (SA)

(21) Appl. No.: 19/121,438

(22) PCT Filed: Nov. 8, 2023
(86) PCT No.: PCT/US2023/036991

§ 371 Date: Apr. 16, 2025

(30) Foreign Application Priority Data
Nov. 8, 2022 (MY) PI2022006282

(51) Int. Cl. G06F 30/20

(52) U.S. Cl. CPC G06F 30/20

(57) ABSTRACT

This invention describes a method of conducting formation evaluation and in particular inferring formation mineralogy when the formation is complex, and when the set of available downhole measurements is limited in information content or quality. One or more embodiments of the method can use a core mineralogy database to generate effective mineral assemblage that captures the natural systematic correlations between series of minerals.

### CROSS-REFERENCE TO RELATED APPLICATIONS

The present application claims priority to Malaysian Patent Application No. PI2022006282, filed on Nov. 8, 2022, which is incorporated by reference herein in its entirety.

### BACKGROUND

### Field

The present disclosure generally relates to formation evaluation and more particularly to inferring formation mineralogy.

### Description of the Related Art

Various methods of formation evaluation have been used in formation petrophysical evaluation using downhole logs is to decide which minerals should be included in the evaluation. This selection is important because it impacts different aspects of the reserves analysis, such as the determination of porosity from typical density or neutron logs it provides information related to the clay content for petrophysics to geomechanics applications, and it helps constraining the estimation of bound fluid volume and permeability.

The selection is often based on mud logs, cutting analysis, core analysis or other sources of direct information. However, criteria to optimize the number of minerals to incorporate in the analysis is not always well-defined. In general, on one hand the higher the number of minerals included, and the higher the accuracy of the evaluation potential is, but, on the other hand, the less robust and prone to noise and biases in the logs the evaluation will be.

This problem is often simplified when downhole elemental spectroscopy tools are used. Such tools provide a set of elemental concentrations in the formation, which can be transformed into sets of minerals using different models.

In a basic triple combo evaluation, the concept of generic shale is used, which encompasses a specific, local assemblage of clays, which endpoint is usually manually optimized in a neutron-density cross-plots. Sometimes historical processing of elemental spectroscopy logs is used. The information content of older generation tools is generally limited, as some elements such as aluminium, potassium, sodium were not estimated with accuracy and precision. As a result, it was difficult with these tools to separate feldspars from clays, and often the feldspars were assembled with quartz and mica to form the well-known Quartz-Feldspar-Mica assemblage. For those tools, different types of clays were also looped together into a generic clay assemblage. Depending on a priori information or some trends in the data, typical deposition setting (for example arenite, sub arkose, arkose) can drive different definition of this “clay” assemblage.

To separate feldspars from clays, and often the feldspars were assembled with quartz and mica to form the well-known Quartz-Feldspar-Mica assemblage. For those tools, different types of clays were also looped together into a generic clay assemblage. Depending on a priori information or some trends in the data, typical deposition setting (for example arenite, sub arkose, arkose) can drive different definition of this “clay” assemblage.

Therefore, there is a need for evaluation that can infer formation mineralogy in a formation when the ser of available downhole measurements is limited in information content and/or quality.

### SUMMARY

A method of conducting formation evaluation by inferring formation mineralogy when a set of available downhole measurements is limited in information content or quality. The method can use the existence of a core mineralogy database to generate effective mineral assemblage that captures the natural systematic correlations between series of minerals.

Once these assemblages are defined, their so-called endpoints can be derived for downhole logs. Depending on the availability of the quality of those downhole logs, and their inherent information content, different sets of assemblages can be used. The larger number of assemblages used, the higher the accuracy of the subsequent evaluation. This evaluation can be based on a solver that estimates the formation properties based on downhole logs, given a set of mineral assemblages and possible downhole fluids.

One or more embodiments can include using a data analytics method on core mineralogical database to automatically derive optimized mineral assemblages. A different set of assemblages, that can be labelled in term of tiers, are definite depending on the desired amount of information content that must be captured

In another embodiments the methods can include using data analytics methods on core elemental concentration database, if available, to enable optimized transform between downhole elemental concentration measurements and minerals assemblages. Use the analysis to optimize processing of cased hole spectroscopy.

The embodiments of the methods can also include defining assemblage endpoints for any logs that may be available for downhole evaluation, and simulating typical ranges of variation for logs to enable efficient real log quality control.

In one or more embodiments, the methods can define which tier of assemblage can be used, depending on the number and quality of logs available for the evaluation.

One or more embodiments of the method can include performing petrophysical evaluation based on selected assemblage set and formation fluids.

### BRIEF DESCRIPTION OF THE FIGURES

Certain embodiments, features, aspects, and advantages of the disclosure will hereafter be described with reference to the accompanying drawings, wherein like reference numerals denote like elements. It should be understood that the accompanying figures illustrate the various implementations described herein and are not meant to limit the scope of various technologies described herein.

FIG. 1 depicts PCA results on a core mineral database. The graph on the left represents the explained variance as function of number of components. The database variance can be characterized at about 99% by 3 to 4 independent components. The graph on the right represents the contribution of each mineral per component.

FIG. 2 depicts a 4-assemblage NNMF analysis result, according to an embodiment of the disclosure; and

FIG. 3 depicts a reconstruction log view of mineralogy based on a 4-assemblage set. In this example, we can observe that 4 assemblages provide a high-fidelity reconstruction of the original mineralogy;

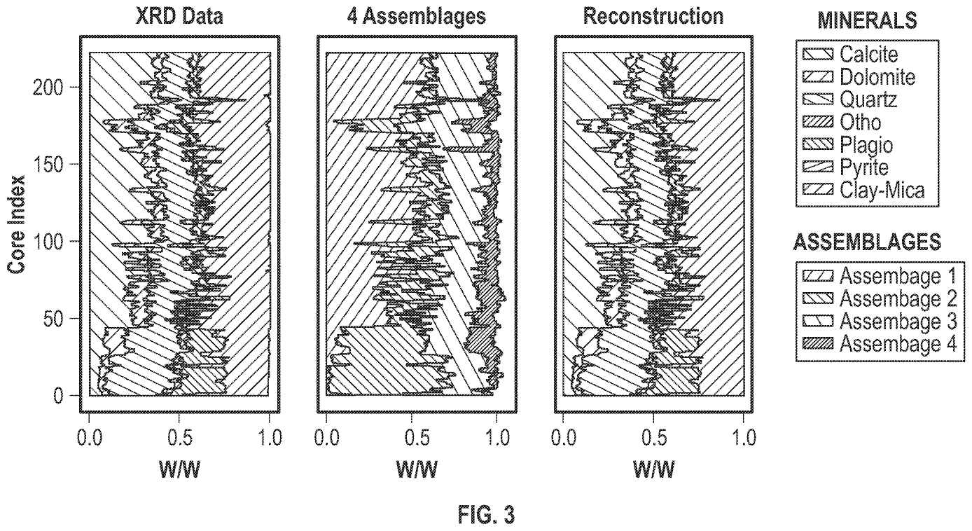

FIG. 4 depicts an example of log forward model simulation to define rang of variation depending on mineralogy and fluid filling the pores (water in blue, gas in red). Track 1 shows the core-based mineralogy. Track 2 shows the 4 assemblage weight fractions and Track 3 shows the reconstructed mineralogy based on assemblage weight fractions. Tracks 4 to 7 show the typical log variations for water (blue) and gas (red) in the pore space. The remaining tracks show series of estimated elemental dry weight fractions, as would be measured by PNL spectroscopy tools.

FIG. 5 depicts an representation of a reconstruction error on mineral database depending on assemblage set tier;

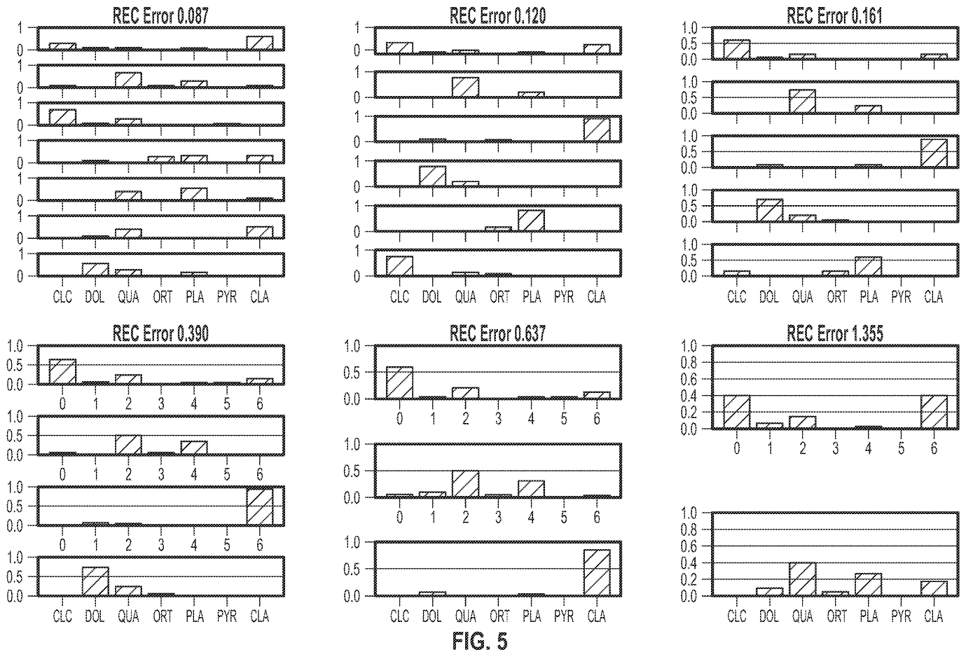

FIG. 6 depicts an example of petrophysical evaluation based on a 4-assemblage tier with water and methane as phases filling the pores. Input logs are Fast Neutron Cross Section (FNXS) neutron porosity (TPHI) formation capture cross section (Sigma) and elemental concentrations (DWXX). Actual measurements are in black, and reconstructed measurement after optimization are in green. Track 1 presents the default mineralogy model provided by the tool. Track 2 presents the assemblage weight fraction estimation and track 3 presents the reconstructed mineralogy from assemblage.

### DETAILED DESCRIPTION

In the following description, numerous details are set forth to provide an understanding of some embodiments of the present disclosure. It is to be understood that the following disclosure provides many different embodiments, or examples, for implementing different features of various embodiments. Specific examples of components and arrangements are described below to simplify the disclosure. These are, of course, merely examples and are not intended to be limiting. However, it will be understood by those of ordinary skill in the art that the system and/or methodology may be practiced without these details and that numerous variations or modifications from the described embodiments are possible. This description is not to be taken in a limiting sense, but rather made merely for the purpose of describing general principles of the implementations. The scope of the described implementations should be ascertained with reference to the issued claims.

As used herein, the terms “connect”, “connection”, “connected”, “in connection with”, and “connecting” are used to mean “in direct connection with” or “in connection with via one or more elements”; and the term “set” is used to mean “one element” or “more than one element”. Further, the terms “couple”, “coupling”, “coupled”, “coupled together”, and “coupled with” are used to mean “directly coupled together” or “coupled together via one or more elements” As used herein, the terms “up” and “down”; “upper” and “lower”; “top” and “bottom”; and other like terms indicating relative positions to a given point or element are utilized to more clearly describe some elements. Commonly, these terms relate to a reference point at the surface from which drilling operations are initiated as being the top point and the total depth being the lowest point, wherein the well (e.g., wellbore, borehole) is vertical, horizontal or slanted relative to the surface.

The disclosed methods and include a first operation of performing a mineral database analysis.

The mineral database analysis can include using a principal component analysis (PCA) on the core mineral database to extract the dimensionality of the database as a function of content of information, by identify independent pieces of information that are necessary to describe the system to a given accuracy. This quantification can be represented by the plot in depicts

While the correlations between minerals and the dimensionality of the system are clarified, the interpretation of each component in term of natural mineral composition is not insightful, as the amount of each mineral can be either positive or unphysically negative. This is not mathematically a problem, but this lack of physical insight may lead to confusion and misuse in subsequent workflows.

An alternate method that ensures independence of components, but at the same time a physical meaning for each component, can then be used.

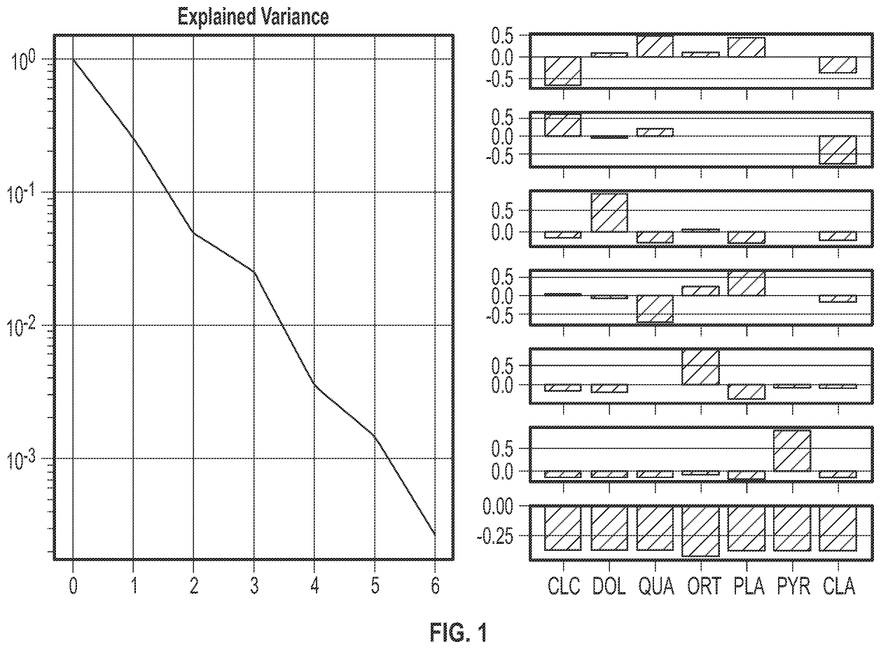

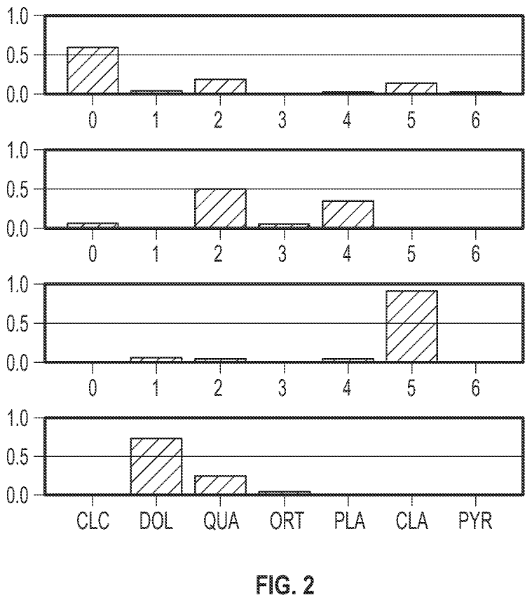

This can include using nonnegative matrix factorization, or NNMF. In this process the components that are obtained are constrained to have positive contribution from each input (mineral). As a results, the components now take a physical meaning in term of positive correlation between elements, as we would expect from geological deposition system. The term assemblage can be used to describe the NNMF component. FIG. 2 shows an example of 4 assemblages on the same database as used for FIG. 1.

The mineral concentration reconstruction error after NNMF process gives an estimate of the excepted accuracy when further using the assemblages for mineralogical analysis. This error is obtained after reconstruction of the individual mineral concentrations from assemblage definition. Depending on the number of components/assemblages solved for, this accuracy will vary. We will call a tier set a set of assemblages for a given accuracy. Low tier means low number of assemblages, and lower accuracy. High tier means higher number of assemblages and improved accuracy.

The method can also include using elemental database analysis. If the database also contains elemental measurements, two optional sub-steps can be conducted. The method can include using the elemental database to extract the elemental composition of each assemblage of each tier set.

The elemental compositions expressed in relative dry weight fraction constitute the elemental spectroscopy endpoints for this assemblage. They can be used in classical multi-mineral solvers to quantify the mineralogy with the support of elemental spectroscopy log.

The method can also include analyzing using the same sequence of PCA and NNMF as for the mineralogical database. This sequence results in sets of elemental assemblages. Those elemental sets can be correlated with mineralogical sets to obtain more robust transforms as compared with multimineral linear solvers.

In addition, these sets can be used to constrain the spectroscopy elemental analysis. Indeed, in cased hole environment, completion offsets need to be applied on some elements that are present both in the formation and in the cement and casing, like iron, calcium silicon, aluminium.

The formation elemental concentrations that result from this offset subtraction process must comply with a given combination of elemental set. Completion offset can be automatically estimated to ensure that resulting formation concentrations do honor a given set of elemental assemblage. A minimal implementation of the automated workflow above is a simple creation of a quality control for formation elemental concentrations in complex conditions.

In one or more embodiments, an alternate method to obtain those spectroscopy endpoints in case no elemental database is available can be used, as described below. For example, one or more embodiments of the method can include a Log endpoint definition.

The log endpoints are defined based on the known response function of each measurement to either minerals or elemental concentration (when available). Common minerals have known endpoint and creating the assemblage endpoint is a straightforward task. Some minerals may have variability in endpoint definition, for example thermal neutron endpoints for clays. In the case where elemental concentrations are available, this difficulty will be mitigated. In the case where no elemental concentration are available, some degree of subjective adjustment will be required.

Table 1 shows an example of endpoint definition for a set of 4 assemblages.

| | A1 | A4 | A2 | A3 |
|---|---|---|---|---|
| RHGE | 2.71 | 2.80 | 2.62 | 2.81 |
| TNGE | 0.02 | 0 | 0 | 0.11 |
| SIGE | 13.24 | 5.05 | 6.49 | 61.3 |
| FNGE | 7.41 | 8.00 | 6.81 | 7.69 |
| DWAL | 0.017 | 0.003 | 0.043 | 0.17 |
| DWCA | 0.25 | 0.16 | 0.029 | 0.01 |
| DWFE | 0.012 | 0 | 0 | 0.025 |
| DWK | 0.004 | 0.004 | 0.008 | 0.066 |
| DWMG | 0.006 | 0.095 | 0.001 | 0.008 |
| DWMN | 0 | 0 | 0 | 0.001 |
| DWNA | 0.002 | 0 | 0.029 | 0.002 |
| DWS | 0.003 | 0 | 0 | 0 |
| DWSI | 0.137 | 0.121 | 0.372 | 0.221 |

The method can also include simulation to define log ranges and quality control criteria based on endpoint definition, a forward model exercise is then performed on the core database to simulate typical range of response for different logs.

This simulation enables: Define which logs are the most sensitive to a target formation parameter. For example, logs with the best sensitivity to gas content, considering the variability of the mineralogy, can be defined; Define log quality controls to ensure that logs acquisition and processing are optimal. For example, the range of variation of Fast Neutron cross section (FNXS) and calcium dry weight fraction can be defined, and hence FNXS borehole correction, and calcium cement offset can be better controlled.

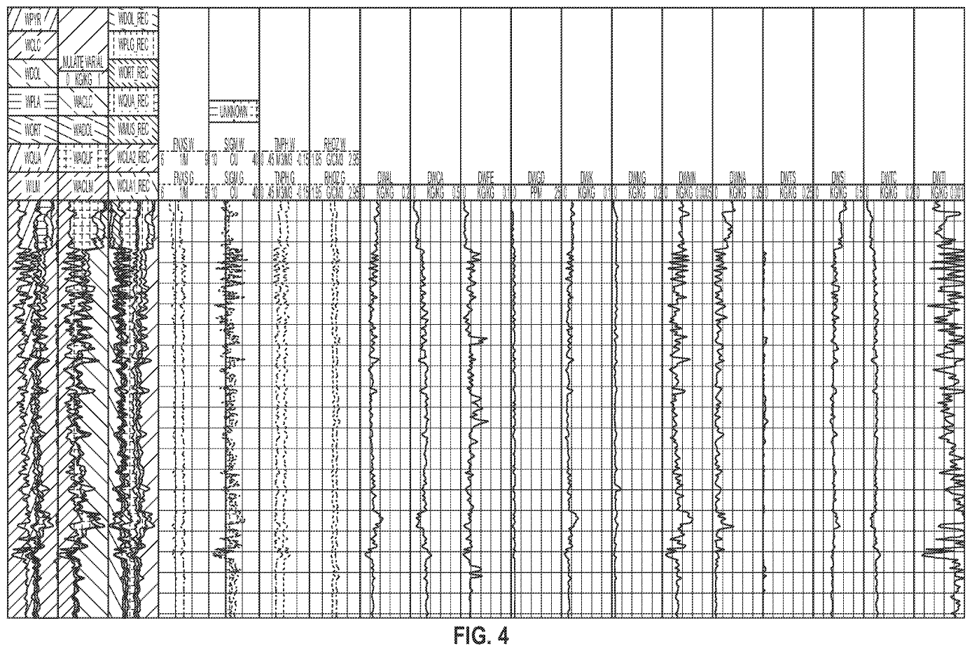

An example of log range definition for a database is show in FIG. 4.

The method can also include defining which assemblage tier must be used. For example, once endpoints are defined, it is possible to use sensitivity analysis to better understand which assemblage tier can be used for a given set of available logs, and by assuming that the transform between logs and mineral and fluid volumes can be locally approximated by a linear forward model that can be inverted, we can express the sensitivity of the inversion process through a sensitivity matrix which is the hessian of the cost function, and that depends on log uncertainties.

Depending on the tier of the assemblage set, different accuracy of mineral reconstruction can be achieved. FIG. 4 shows an example of different reconstruction errors as a function of assemblage set tier (equivalent to number of components selected).

The decision of which set to ultimately use will depend on a balance between expected mineralogical accuracy and propagation of log uncertainty to assemblage uncertainty based on sensitivity analysis. The tiering (reconstruction accuracy) of the assemblage must be of the same order than the log error propagation uncertainty.

The method can also include performing petrophysical evaluation based on selected assemblage tier and fluids. For example, once a tier set of assemblage is selected, common and ad-hoc solvers can be used in this final step to invert the measurements log into mineral concentrations (or dry weight fractions) and fluid/gas volume fractions. It is important at the end of the process to compute the a posteriori reconstruction of the logs and compare with the input logs. It provides a measure of the quality of the process and can possibly point out some biases in the measurements.

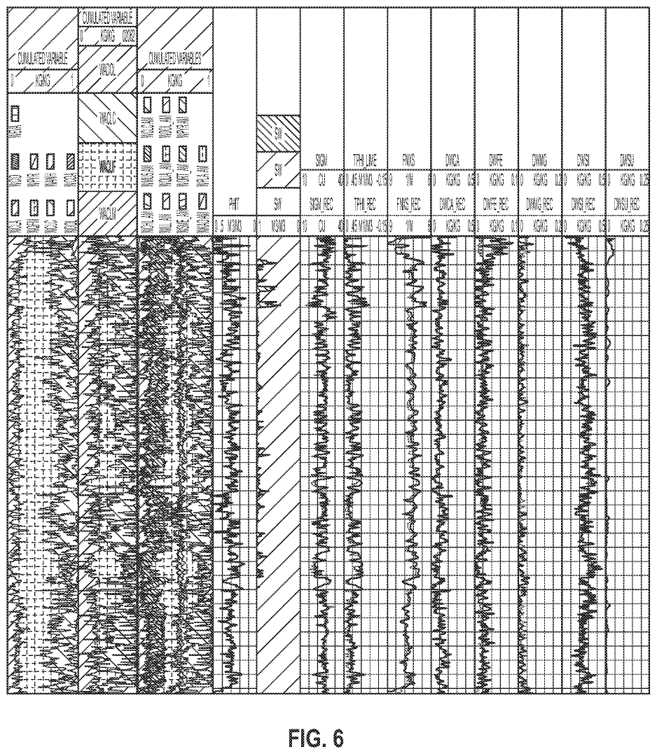

FIG. 6 shows an example of application with real log processing based on a 4-assemblage selection, with water and gas in the formation, when elemental concertation's, fast neutron cross section (FNXS), Sigma and neutron porosity (TPHI) logs are available

An embodiment of the method can include using a PCA and NNMF methods on core mineralogical database to automatically derive optimized mineral assemblages. Derive different tiers of assemblage sets enabling varying reconstruction fidelity levels. Optionally, use data analytics methods on core elemental concentration database, if available, to enable optimized transform between downhole elemental concentration measurements and minerals assemblages. Use assemblage analysis to optimize processing of cased hole spectroscopy. Define log endpoints of said assemblages, of said tier sets. Simulate typical ranges of variation for logs to enable efficient selection of most sensitive logs to run. Simulate typical ranges of variation for logs to enable efficient real log quality control, and using a method to define which tier of assemblage can be used, depending on the number and quality of logs available for the evaluation.

The method can also include performing a petrophysical evaluation based on selected assemblage set and formation fluids

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and/or within less than 0.01% of the stated amount. As another example, in certain embodiments, the terms “generally parallel” and “substantially parallel” or “generally perpendicular” and “substantially perpendicular” refer to a value, amount, or characteristic that departs from exactly parallel or perpendicular, respectively, by less than or equal to 15 degrees, 10 degrees, 5 degrees, 3 degrees, 1 degree, or 0.1 degree.

Although a few embodiments of the disclosure have been described in detail above, those of ordinary skill in the art will readily appreciate that many modifications are possible without materially departing from the teachings of this disclosure. Accordingly, such modifications are intended to be included within the scope of this disclosure as defined in the claims. It is also contemplated that various combinations or sub-combinations of the specific features and aspects of the embodiments described may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above.

What is claimed is:

1. A method of formation evaluation comprising:
a. using principal component analysis and nonnegative matrix factorization methods on a core mineralogical database to automatically derive optimized mineral assemblages;
b. deriving different tiers of assemblage sets enabling varying reconstruction fidelity levels;
c. using an assemblage analysis to optimize processing of cased hole spectroscopy;
d. defining log endpoints of said assemblages, of said tier sets;
e. simulating typical ranges of variation for logs to enable efficient selection of most sensitive logs to run;
f. simulating typical ranges of variation for logs to enable efficient real log quality control;
g. using a method to define which tier of assemblage can be used, depending on a number and quality of logs available for the evaluation; and
h. performing a petrophysical evaluation based on a selected assemblage set and formation fluids.

2. The method of formation evaluation according to claim 1, further comprising estimating a mineral concentration reconstruction error after using principal component analysis—and nonnegative matrix factorization—methods on a core mineralogical database

3. The method of formation evaluation according to claim 1, further comprising using an elemental database analysis after the using principal component analysis and nonnegative matrix factorization methods on a core mineralogical database

4. The method of formation evaluation according to claim 1, further comprising constraining the cased hole spectroscopy prior to optimization.

5. The method of formation evaluation according to claim 1, wherein the log end points are defined based on a known response function.

6. The method of formation evaluation according to claim 5, wherein the known response function is related to one of a mineral and elemental concentration.

7. The method of formation evaluation according to claim 1, wherein the performing the petrophysical evaluation based on the selected assemblage set and formation fluids includes measuring a quality of the petrophysical evaluation.

8. A method of formation evaluation comprising:
a. using principal component analysis and nonnegative matrix factorization methods on core mineralogical database to automatically derive optimized mineral assemblages;
b. using data analytics methods on a core elemental concentration database, enabling optimized transform between downhole elemental concentration measurements and minerals assemblages;
c. using an assemblage analysis to optimize processing of cased hole spectroscopy;
d. defining log endpoints of said assemblages, of said tier sets;
e. simulating typical ranges of variation for logs to enable efficient selection of most sensitive logs to run;
f. simulating typical ranges of variation for logs to enable efficient real log quality control;
g. using a method to define which tier of assemblage can be used, depending on the number and quality of logs available for the evaluation; and
h. performing petrophysical evaluation based on selected assemblage set and formation fluids.

9. The method of formation evaluation according to claim 8, further comprising estimating a mineral concentration reconstruction error after using principal component analysis—and nonnegative matrix factorization—methods on a core mineralogical database

10. The method of formation evaluation according to claim 8, further comprising using an elemental database analysis after the using principal component analysis and nonnegative matrix factorization methods on a core mineralogical database

11. The method of formation evaluation according to claim 8, further comprising constraining the cased hole spectroscopy prior to optimization.

12. The method of formation evaluation according to claim 8, wherein the log end points are defined based on a known response function.
